(19) United States
(12) Patent Application Publication
(10) Pub. No.: US 2024/0258214 A1
(43) Pub. Date: Aug. 1, 2024

(54) PACKAGED ELECTRONIC DEVICES AND METHODS OF MAKING SAME

(71) Applicant: TEXAS INSTRUMENTS INCORPORATED, DALLAS, TX (US)

(72) Inventors: Makoto SHIBUYA, Tokyo (JP); Kengo AOYA, Beppu-shi Oita-Ken (JP)

(21) Appl. No.: 18/162,144

(22) Filed: Jan. 31, 2023

(51) Int. Cl. H01L 23/495; H01L 21/56; H01L 23/31

(52) U.S. Cl. CPC H01L 23/49565; H01L 21/561; H01L 21/565; H01L 23/3107; H01L 24/48; H01L 2224/48175

(57) ABSTRACT

An example electronic device includes a substrate having a die pad and a semiconductor device on the die pad electrically connected to the substrate. The device also includes a mold compound over the semiconductor device to provide a packaged electronic device. The packaged electronic device has respective side edges that extend from a first end to terminate in a second end at a distal surface of the mold compound that is spaced apart from the substrate. At least one side edge of the mold compound has a respective surface that is orthogonal to the distal surface and includes a notch extending inwardly from the respective surface.

### TECHNICAL FIELD

This description relates to packaged electronic devices and to methods of making packaged electronic devices.

### BACKGROUND

In order to package integrated circuit devices, such as processors, memories, logic units, power supplies, and the like, singulated die are placed on a lead frame. A mold tool is configured to encapsulate each integrated circuit device in a molding material. Because of the molding process, mold flash can occur. Mold flash can affect the number of units that can be fabricated over time (e.g., production rate) and, ultimately, reduce production yield.

### SUMMARY

One described example relates to electronic device includes a substrate having a die pad and a semiconductor device on the die pad electrically connected to the substrate. The device also includes a mold compound over the semiconductor device to provide a packaged electronic device. The packaged electronic device has respective side edges that extend from a first end to terminate in a second end at a distal surface of the mold compound that is spaced apart from the substrate. At least one side edge of the mold compound has a respective surface that is orthogonal to the distal surface and includes a notch extending inwardly from the respective surface.

Another example relates to a method that includes mounting semiconductor devices on die pads of respective lead frames distributed across a substrate having first and second surfaces.

The method also includes positioning a first mold chase on the first surface of the substrate over the semiconductor devices. The first mold chase includes an arrangement of protrusions extending from a surface of a mold cavity aligned with respective edges of the die pads between adjacent pairs of the lead frames. The method also includes positioning a second mold chase on the second surface opposite the first mold chase to clamp the substrate between the first and second mold chases. The method also includes injecting a mold compound into the mold cavity to encapsulate the semiconductor devices and portions of the substrate. The method also includes singulating the semiconductor devices to provide packaged semiconductor devices.

Another described example relates to a packaged electronic that includes a lead frame having a die pad and contacts along at least one side thereof. An electronic device is on the die pad, and the electronic device includes pads coupled to respective ones of the contacts. A mold compound is over the electronic device to provide an encapsulated electronic device, in which the encapsulated electronic device has first and second pairs of opposing sides and a planar distal surface spaced from the lead frame. The contacts at least partially exposed through the mold compound along the at least one of the first pair of sides. The mold compound along the second pair of opposing sides has respective surfaces that are orthogonal to the distal surface and includes a respective notch therein.

### BRIEF DESCRIPTION OF THE DRAWINGS

FIGS. 1 and 2 are isometric views of an example packaged electronic device.

FIG. 3 is a flow diagram of a method of making a packaged electronic device.

FIG. 4 is a plan view of a lead frame sheet having respective dies attached to respective die pads.

FIG. 5 is a side sectional view of a packaging mold attached to the lead frame sheet of

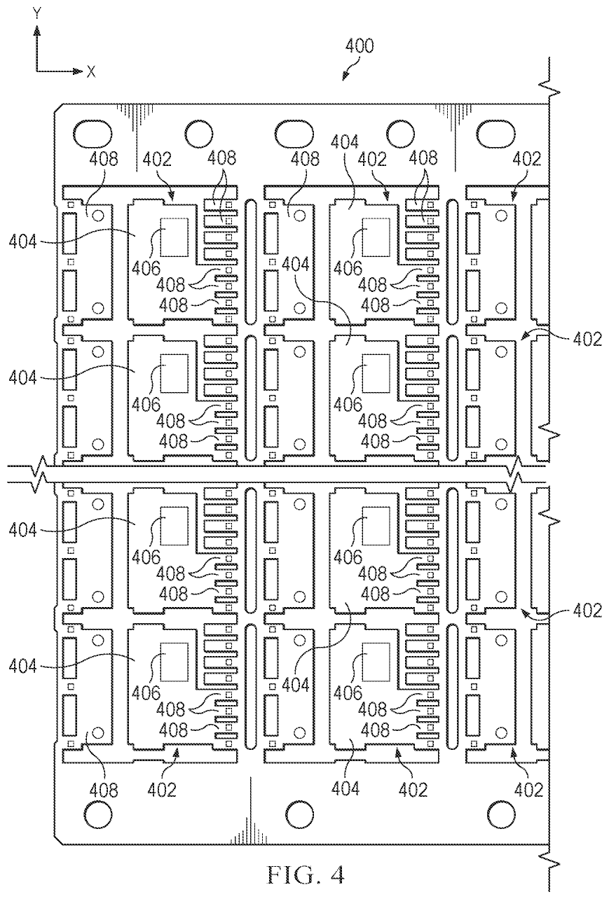

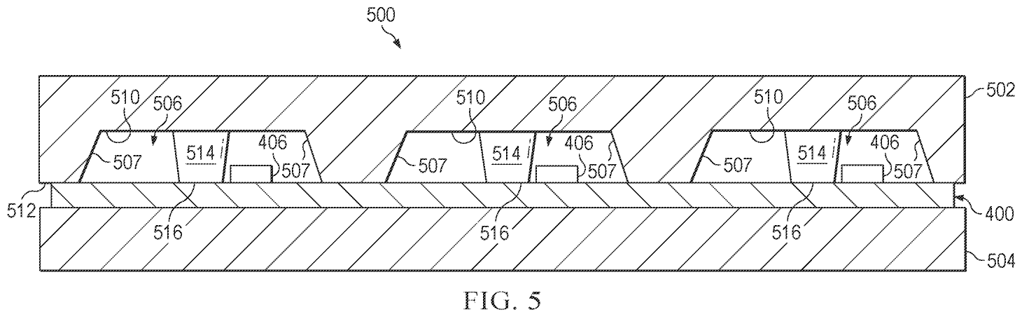

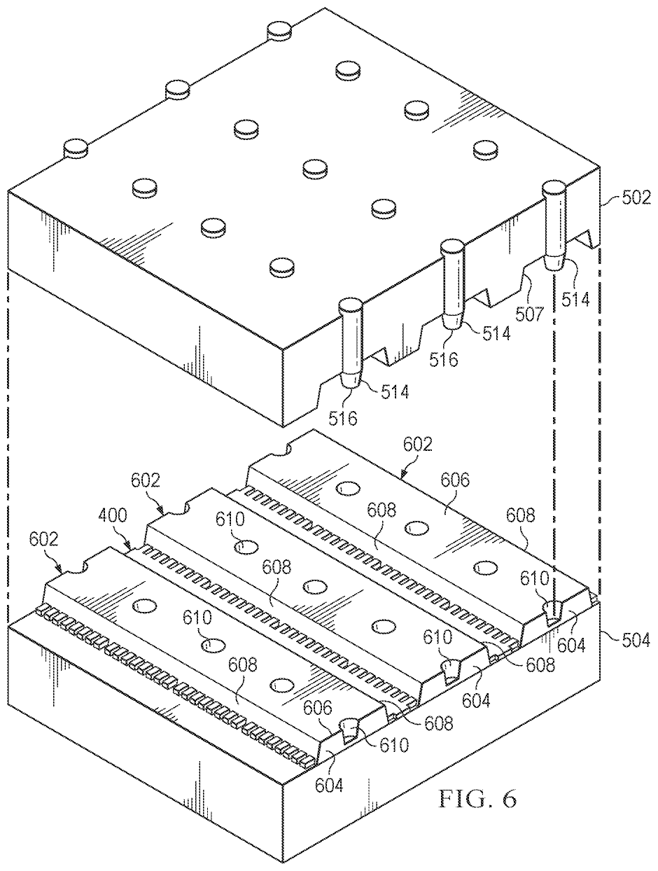

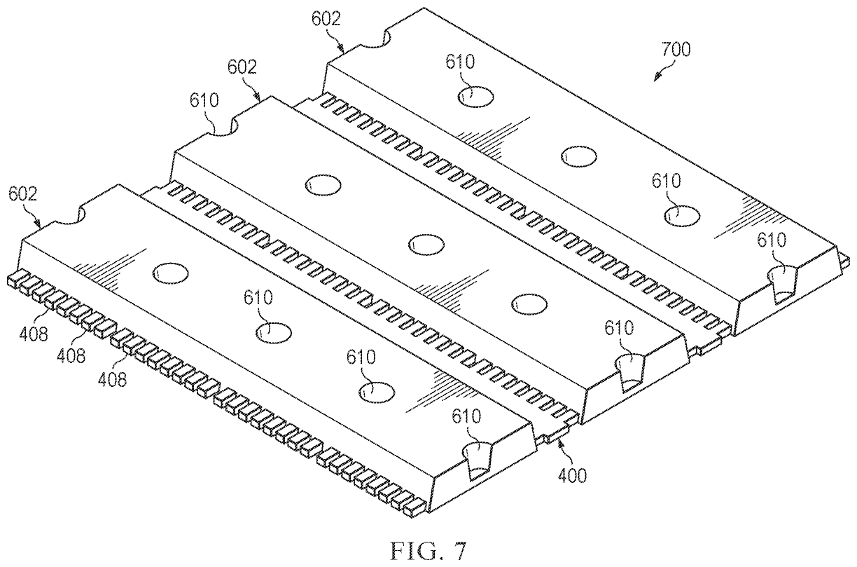

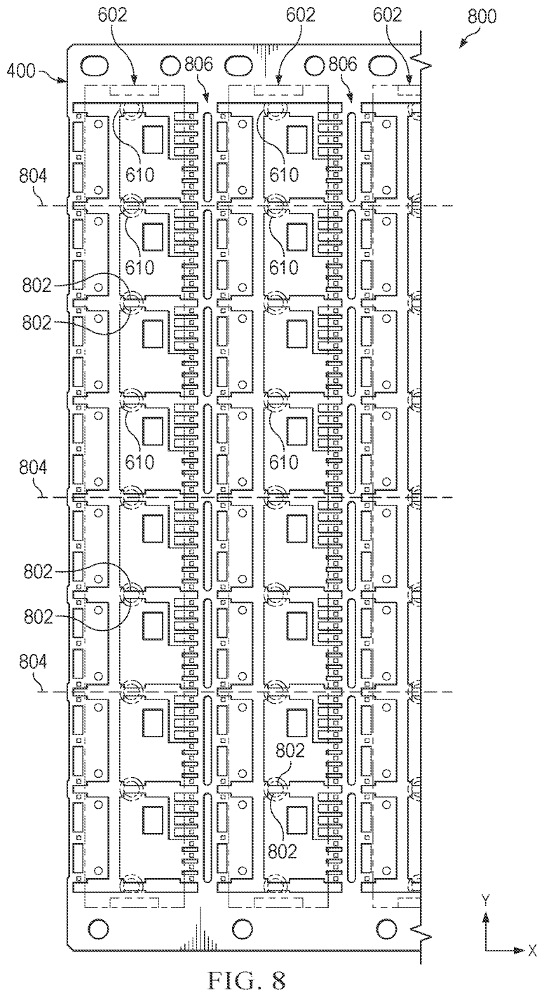

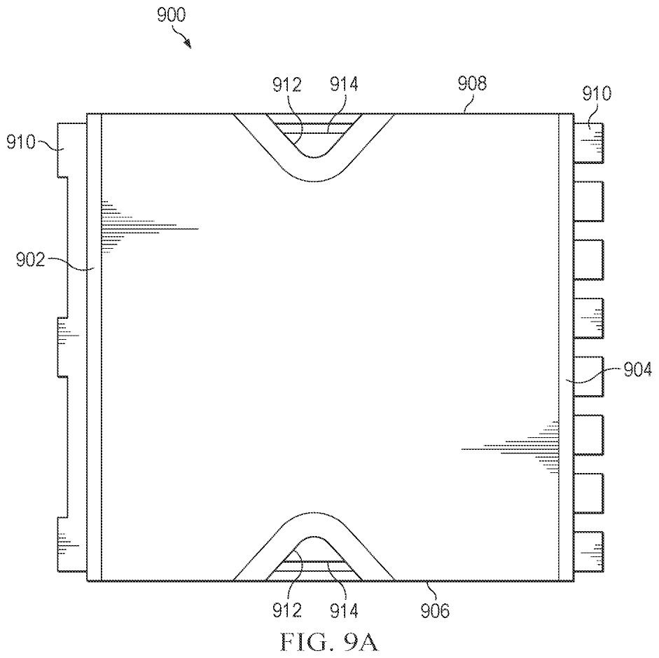

FIG. 4.

FIG. 6 is an isometric view showing part of a top mold chase of the packaging mold of

FIG. 4 being separated from the lead frame sheet after encapsulation.

FIG. 7 is an isometric view showing an example the lead frame sheet of FIG. 6 after encapsulation and remove of mold chases.

FIG. 8 is a plan view of another example lead frame sheet after encapsulation.

FIGS. 9A, 9B, 9C, 9D and 9E are respective plan and several side views showing an example of a packaged electronic device after singulation.

### DETAILED DESCRIPTION

This description relates to packaged electronic devices and to methods of making packaged electronic devices, such as packaged integrated circuits (ICs).

In an example, a packaged electronic device includes a lead frame having a die pad and contacts along at least one side thereof. An electronic device (e.g., an IC die) is mounted on the die pad, such as through a die attach process. The electronic device includes pads coupled to respective ones of the contacts. For example, wire bonding can be used to electrically couple contacts and bond pads. A mold compound is applied to encapsulate the electronic device, and the encapsulated device has first and second pairs of opposing sides and a planar distal surface spaced from the lead frame. The contacts are at least partially exposed through the mold compound along at least one of the first pair of sides. The mold compound along the second pair of opposing sides has respective surfaces, in which each of the surfaces of the second pair of opposing sides is orthogonal to the distal surface and includes a respective notch therein. The respective notches can be formed from a feature of a mold that is used for contacting and clamping the die pad between mold chases during encapsulation.

As a further example, the fabrication of the packaged electronic device can be performed by clamping a sheet of lead frames between first and second mold chases. A plurality of electronic devices can be mounted on respective die pads of a first surface of the sheet. The first mold chase can be positioned on the first surface of the sheet over semiconductor devices. The first mold chase includes an arrangement of protruding features (e.g., tubular clamping) extending from an inner surface of a mold cavity to terminate in respective distal ends. The protruding features are aligned with respective edges of the die pads between adjacent pairs of the lead frames. The second mold chase is positioned on the second surface of the sheet opposite the first mold chase to clamp the substrate between the first and second mold chases, in which the protruding features are configured to clamp the edges of the die pads with an opposing surface of the second mold chase. mold compound can then be injected into the mold cavity to encapsulate the semiconductor devices, as described herein. By this method, the mold compound can form a unified volume of the mold compound encapsulating an arrangement (e.g., a row or column) of the electronic device devices with voids being formed at the respective locations of each of the protrusions. The individual packaged electronic devices can be singulated from the sheet, such as by cutting through the lead frame sheet and mold compound in a direction between adjacent pairs of the lead frames and through the voids. The cutting through the voids forms the respective notches along the second pair of opposing sides of each packaged semiconductor device. The cutting also forms the vertically extending surfaces on the second pair of opposing sides, which sides are also free from contacts for the electronic device. The surface of the mold compound along the first pair of opposing side edges extends between respective ends of the first side edges can taper from the substrate to the distal surface according to configuration of the inner surface of the first mold chase.

As described herein, the method of making the device enables an increased number of unit density on a lead frame sheet, which can increase yield. Additionally, the packaged electronic device exhibits reduced mold flash, which is attributable to the increased clamping force across the lead frame between respective mold chases.

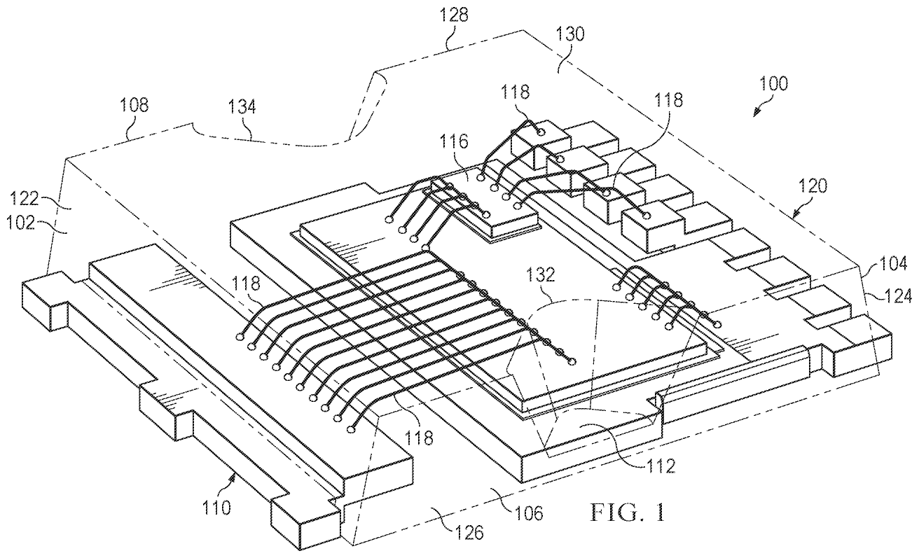

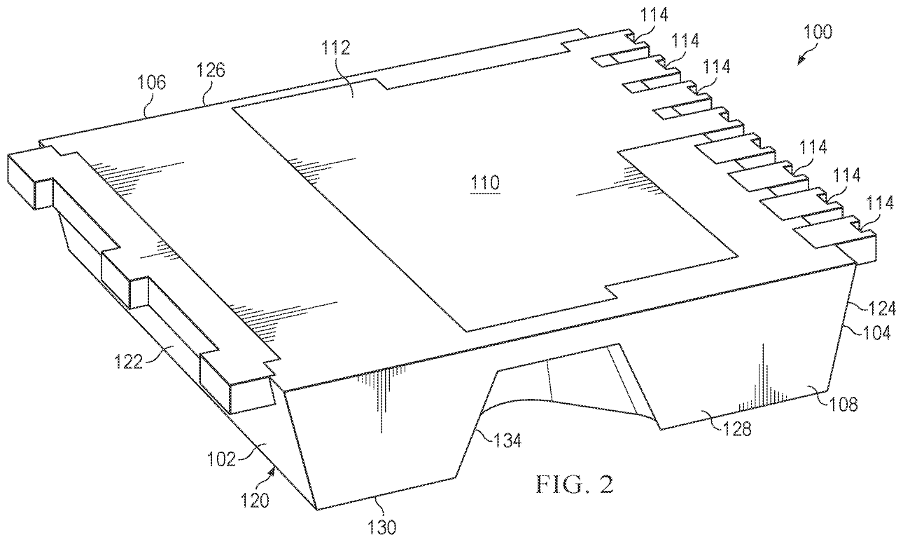

FIGS. 1 and 2 depict respective top and bottom isometric views of an example packaged (e.g., encapsulated) electronic device 100. The packaged device 100 can be a packaged semiconductor device, such as an IC package or a system on chip (SOC) package. The packaged device 100 has a first pair of opposing sides 102 and 104 and a second pair of opposing sides 106 and 108. The packaged device also includes a substrate 110 having a die pad 112. For example, the substrate 110 is a lead frame, which includes the die pad 112 and has a plurality of contacts 114 along at least one side thereof, such as shown in FIG. 2. In the example of FIGS. 1 and 2, the substrate 110 includes an arrangement of contacts 114 along each of the opposing sides 102 and 104 of the substrate (e.g., lead frame). The substrate 110 can be formed of an electrically conductive material, such as a metal (e.g., copper, aluminum, or another metal).

As shown in FIG. 1, the packaged device 100 includes one or more electronic devices 116 mounted on the die pad 112 of the substrate 110. For example, the electronic device 116 includes a having a top side with conductive terminals (e.g., copper bond pads) configured to electrically couple to respective leads of the lead frame. The terminals (e.g., bond pads) of the die can be electrically coupled to respective contacts 114, such as through bond wires 118. The number and locations of the contacts 114 can vary depending on the configuration of the electronic device(s) 116 and the type of package. Examples of some types of packages can be used to make include single row packages (e.g., single inline packages) and dual row packages (e.g., dual inline packages, flat back packages, small outline integrated circuit packages), quad row packages (e.g., quad flat no leads (QFN) or quad flat packages) and transistor outline (e.g., transistor outline leadless (TOLL)) packages.

The packaged device 100 includes a mold compound 120 formed over the electronic device 116 and bond wires 118. The mold compound 120 can be a plastic or epoxy material. The mold compound 120 has respective edge surfaces 122, 124, 126 and 128 on respective sides 102, 104, 106 and 108. Each of the surfaces 122, 124, 126 and 128 extends from a first end thereof at the substrate 110 to terminate in a second end at a distal planar surface 130 of the mold compound (e.g., a top surface of the packaged device 100) that is spaced apart from the substrate 110. Thus, as shown in FIGS. 1 and 2, the mold compound 120 encapsulates the electronic device 116, bond wire 118, and a portion of the substrate 110 to form the packaged electronic device 100. The packaged electronic device 100 can be referred to as “encapsulated”, although the term “encapsulated” as used herein includes portions of the substrate 110 and contacts 114 that are exposed, and not covered by the mold compound 120, to provide electrical terminals for the finished packaged device 100.

The packaged device 100 includes one or more side surfaces that are orthogonal to the distal surface 130 of the mold compound 120. In the example of FIGS. 1 and 2 (also see, e.g., FIGS. 8B and 8C) opposing side surfaces 126 and 128 of respective sides 106 and 108 are orthogonal to the planar surface of the substrate 110 and/or the distal surface 130 of the mold compound 120. The opposing side surfaces 126 and 128 can also be parallel to each other. For example, the orthogonal side surface(s) 126 and 128 can be formed during singulation by cutting (e.g., with a saw) through the saw streets between adjacent lead frames after encapsulation. Because of such cutting, the orthogonal opposing side surfaces 126 and 128 thus are free from contacts for the electronic device. Instead, the contacts 114 are along one or both of the other sides 102 and 104.

One or more of the opposing side surfaces 126 and 128 also includes a respective notch 132 and 134 extending inwardly from the respective surface. Each of the notches 132 and 134 also extends from a mounting surface of the substrate 110 to the distal surface 130 of the mold compound. The notch is thus configured to expose a portion of the die pad 112. As an example, the notches 132 and 134 can be formed by clamping features of a respective mold chase that is used to encapsulate the device with the mold compound 120. Thus, the notches have respective contour corresponding to the contour of an outer surface of the clamping features. As shown in FIGS. 1 and 2, the notches 132 and 134 have a curved surface that tapers inwardly from the distal surface 130 to the exposed portion of the die pad 112 that resides within the wall of the notches. Other notch shapes, with or without tapering sidewalls, can be used in other examples.

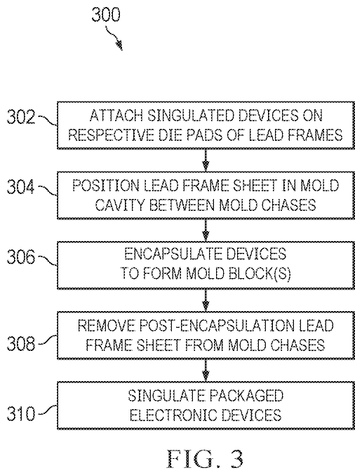

FIG. 3 is a flow diagram showing an example method 300 of making a packaged electronic device. The method 300 is described in relation to various views of FIGS. 4-9, which show an example processing progression for fabricating a packaged semiconductor device according to the method 300.

At 302, the method 300 includes attaching singulated electronic devices on respective die pads of lead frames, which are distributed across a lead frame sheet (or strip). For example, FIG. 4 shows a portion of a lead frame sheet 400 that includes a plurality of lead frames 402. The sheet 400 can be formed of an electrically conductive material, such as a metal (e.g., copper, aluminum, or another metal). In the example of FIG. 4, the lead frames 402 are arranged in rows along a first direction (e.g., an X-direction) and in columns a long a second direction (e.g., a Y-direction). The first and second directions are orthogonal to each other and can define a virtual plane extending through the lead frame sheet 400. Each lead frame 402 includes one or more die pads 404 on which respective singulated electronic devices 406 have been attached.

For example, each singulated electronic device 406 is a die has been separated or singulated from a wafer on which integrated circuitry has been formed. Each die has a bottom side of the die that is placed on and attached to a surface of a die pad of a lead frame during the attachment at 302, such as using pick and place equipment. The top side of the die has conductive terminals (e.g., copper bond pads) for electrically coupling to respective contacts (or pads, such as a ground pad) 408 of the lead frame 402. In the example of FIG. 4, the contacts 408 are located along opposing sides of the respective lead frames 402.

As part of the device attachment at 302, for example, each die undergoes an electrical connection process to electrically couple contacts of respective lead frames to respective terminals of the dies, such as by using bond wires. In another example, the electrical connection at 302 includes flip-chip die attach techniques to electrically couple given respective terminals of the die to respective leads, alone or in combination with wire bonding.

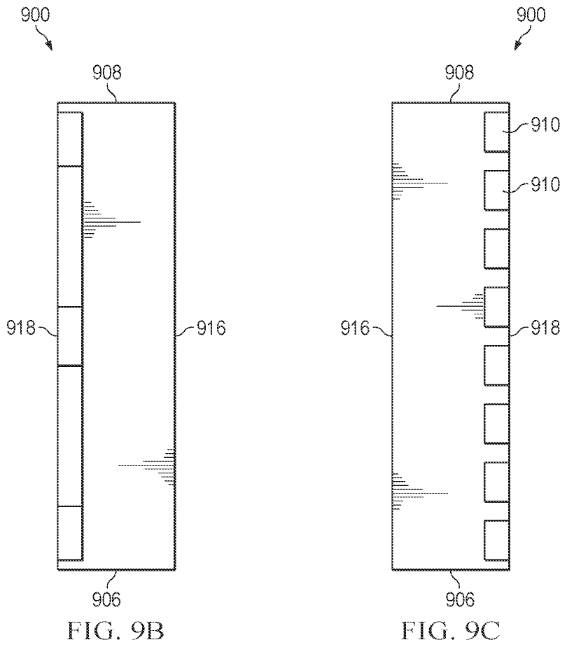

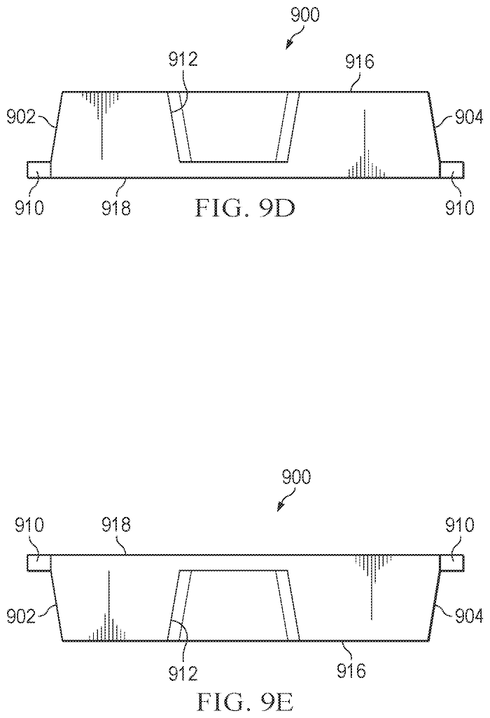

At 304, the method 300 includes positioning the lead frame sheet (or a portion thereof) in a mold cavity between mold chases. For example, FIG. 5 is a side sectional view of a packaging mold 500 attached to the lead frame sheet 400 of FIG. 4, in which a first mold chase is positioned on the first surface of the substrate over the semiconductor devices 406 and a second mold chase 504 is positioned on the second surface opposite the first mold chase. The first and second mold chases 502 and 504 are configured to clamp the lead frame sheet between the respective mold chases. Each of first and second mold chases 502 and 504 can include one or more respective mold cavities (also referred to as semiconductor die cavities). The mold cavities are configured to receive a volume of a mold compound as described herein.

In the example of FIG. 5, the first mold chase 502 includes a plurality of mold cavities 506, in which each mold cavity has a length and volume configured to contain multiple lead frames 402 and devices 406 arranged in a respective column on the first surface of the lead frame sheet 400. Referring to FIG. 4, each the mold cavities 506 of the mold chase 502 thus extends longitudinally in the Y-direction over a set of lead frames 402 arranged in a respective column. A given mold cavity can extend the length of an entire column between edges of lead frame sheet 400, as to accommodate all lead frames 402 and respective semiconductor dies in such column. Alternatively, a given mold cavity of the mold chase 502 can extend part of a column, such as to accommodate a set of two or more lead frames in such column.

Referring back to FIG. 5, each mold cavity 506 can include opposing sidewall surfaces 507 along opposite edges of the respective cavity. The sidewall surfaces 507 extend from a proximal end 510 of the mold cavity 502 and terminate at a distal end 512 of the cavity. Each of the sidewall surfaces 507 tapers inwardly from the distal end 512 of a respective cavity 506 toward the proximal end 510 of the respective cavity. For example, the angles formed between the surfaces at 512 and 507 are obtuse angles (e.g., to facilitate the removal of mold chase 502 from the packaged electronic devices after molding is complete). Also, while the mold chase 502 in FIG. 5 is shown as including three mold cavities 506, there can be any number of such mold cavities in the mold chase, such as can be configured depending on the size and configuration of the lead frame sheet 400.

The first mold chase 502 also includes an arrangement of protrusions (e.g., clamping features) 512 extending from the proximal end 510 of the mold cavity 506 to terminate in a clamping end 516 thereof. The clamping end 516 of each protrusion 514 is configured to align with an edge of one or more die pads (die pads 404). For example, each respective protrusion 514 is configured to clamp the edge of a respective die pad to a clamping surface of the opposing mold chase 504 (including during injection of the mold compound). As a further example, the clamping end 516 of each respective protrusion 514 is configured to align with and clamp respective edges of the die pads that are free of contacts 408 and located between adjacent pairs of lead frames 402. In an example, each of the protrusions 514 tapers inwardly along its length from the proximal end 510 of the cavity toward the distal clamping end 516 (e.g., to facilitate the removal of mold chase 502 from the packaged electronic devices after molding is complete). The protrusions 514 thus taper in a direction that is opposite from the direction of taper for sidewall surfaces 507. Each of the protrusions can have a cross-sectional shape that is circular, rectangular, or other polygonal shape.

At 306, the method 300 includes injecting mold compound into one or more mold cavities to encapsulate the electronic devices and form one or more mold blocks. For example, the mold compound is injected while the lead frame sheet is clamped between respective mold chases 502 and 504, such as shown in FIG. 5. As used herein, encapsulation refers to a covering of the mold compound (e.g., plastic or epoxy material) over the dies 406 and bond wires, and partially covering the lead frames, so that portions of the contacts 408 may be exposed.

The mold chase design with such protrusions 514 can thus be used to effectively encapsulate lead frame sheets having an increased density of lead frames (compared to existing lead frame sheets) due to reduced spacing between rows of lead frames. By using the protrusions 514 as clamping features to provide additional clamping force on respective die pads (at 306), mold flash can be reduced compared to approaches that would implement encapsulation without such protrusions within the mold cavities. As a result, overall yield and number of units produced over time can be increased compared with existing approaches.

At 308, the method 300 includes removing the post-encapsulation lead frame sheet from mold chases. This alternatively also could be described as removing the mold chases from the post-encapsulation lead frame sheet. For example, FIG. 6 is an isometric view showing part of a top mold chase 502 being removed from the lead frame sheet 400 after encapsulation (at 306). FIG. 7 is an isometric view showing an example an encapsulated lead frame sheet 700 after encapsulation and removal of mold chases in FIG. 6. As shown in FIGS. 6 and 7, the encapsulation includes one or more elongated mold blocks 602 of mold compound attached to the lead frame sheet extending over a set of respective dies, lead frames and bond wires (if any). Each of the mold blocks 602 includes a volume of the mold compound and has a shape provided the respective mold cavity (e.g., mold cavity 506) of the mold chases 502 and 504. In the example of FIGS. 6 and 7, each of the mold blocks 602 has a trapezoidal cross-sectional shape, in which a width of mold block 602 at a proximal end (e.g., at the lead frame sheet 400) 604 is greater than a width at a distal end 606 thereof distal surface. Each mold block also has side edges 608 extending between proximal and distal ends 604 and 606, tapering inwardly toward each other away from the lead frame sheet 400. The surface at the distal end 606 of the mold blocks 602 can be a planar surface that is parallel to an opposite planar surface at the proximal end 604. Other cross-sectional shapes (e.g., rectangular, semicircular, polygonal, etc.) can be provided in other examples.

Each of the mold blocks 602 also includes an arrangement of voids (also referred to herein as apertures) 610 extending from the lead frame sheet 400 through the surface at the distal end 606. The apertures 610 are formed during encapsulation by the respective protrusions (e.g., clamping mold features) 514 clamping a portion of the lead frame sheet (at edges of die pads of adjacent lead frames) between the clamping end 516 and the opposing surface of the mold chase 504 to thereby preventing flow of mold compound during encapsulation processing at 306. As a result, the apertures 610 are located over and expose edges of respective die pads of adjacent lead frames. Each aperture 610 has a shape defined by the configuration of the respective protrusions 514 within the mold cavities of the mold chase 502. For example, each aperture has a conical-frustrum shape, such as tapering inwardly from the end surface 606 to the exposed portion of the lead frame sheet 400. Other shapes can be used (e.g., polygonal cylinders or circular cylinders).

FIG. 8 is a plan view of another example of an encapsulated lead frame sheet 800 after encapsulation processing (at 308) of the of the lead frame sheet 400 of FIG. 4. In the example of FIG. 8, the encapsulated lead frame sheet 800 has mold blocks 602 that are partially transparent to show features of the respective lead frames 402. As shown in FIG. 8, the apertures 610 are configured to expose edges 802 of die pads from adjacent lead frames, which is a result of additional clamping provided by distal ends of mold protrusions when mold chases 502 and 504 are forced together during encapsulation processing (at 306). Also, each of the apertures are formed over saw streets 804 extending in the X-direction across the lead frame sheet 400 between adjacent rows of lead frames 402. For example, a center of each aperture 610 is aligned with a respective saw street 804 and a periphery of the aperture extends over edges 802 of respective die pads of an adjacent pair of lead frames. The lead frame sheet 400 also includes dam bars 806 extending in the Y-direction between adjacent columns of lead frames 402.

At 310, the method includes singulating packaged electronic devices. For example, the singulation at 310 uses a rotating cutting saw blade that is configured to cut through the encapsulated lead frame sheet 700, 800 along respective saw streets 804 (in the X-direction between rows of lead frames) and to translate the saw blade to cut along respective dam bars 806 (in the Y-direction between columns of lead frames-in examples when there are more than columns). FIGS. 9A, 9B, 9C, 9D and 9E show an example of a singulated packaged electronic device (e.g., an IC) 900 from a variety of different views. FIG. 9A is a top plan view of the packaged device 900, and FIGS. 9B, 9C, 9D and 9E are different side views of the device 900. The packaged device 900 has a first pair of opposing sides 902 and 904 and a second pair of opposing sides 906 and 908. In the example of FIGS. 9A, 9B, 9C, 9D and 9E, the resulting packaged device includes an arrangement of contacts 910 along each of the opposing sides 902 and 904 of the substrate (e.g., lead frame). Each of the other sides 906 and 908 are free from contacts. Each of the other sides 906 and 908 also includes respective notches 912, which are formed by cutting along saw streets 804 through respective apertures 610. Each notch 912 thus is part of (e.g., approximately half of) an aperture. Each notch 912 also exposes part of an edge portion of a die pad 914 along the respective sides 906, 908. The packaged device 900 also includes opposing top and bottom surfaces 916 and 918, which can be planar and parallel to each other, such as shown in FIGS. 9B and 9C. The singulation (at 310) also forms the surfaces of the opposing pair of sides 906 and 908 to be orthogonal to a planar surface 916 and/or 918. Thus, the surfaces at opposing pair of sides 906 and 908 can also be parallel to each other. The other pair of opposing sides 902 and 904 can have respective surfaces tapering from a first width at the surface 918 to a second width at the surface 916 (the second width being less than the first width), as shown in FIGS. 9D and 9E.

In this description, numerical designations “first”, “second”, etc. are not necessarily consistent with same designations in the claims herein. Additionally, the term “couple” may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. An electronic device comprising:
a substrate having a die pad;
a semiconductor device on the die pad and electrically connected to the substrate; and
a mold compound over the semiconductor device to provide a packaged electronic device having respective side edges that extend from a first end to terminate in a second end at a distal surface of the mold compound that is spaced apart from the substrate, in which at least one side edge of the mold compound has a respective surface that is orthogonal to the distal surface and includes a notch extending inwardly from the respective surface.

2. The device of claim 1, wherein the mold compound includes a pair of opposing side edges having respective surfaces, in which each of the surfaces of the opposing side edges is orthogonal to the distal surface and includes a respective notch therein.

3. The device of claim 2, wherein the opposing side edges are free from contacts for the electronic device.

4. The device of claim 3, wherein the opposing side edges have respective surfaces that are parallel to each other and orthogonal to the distal surface of the mold compound.

5. The device of claim 2, wherein the pair of opposing side edges is a pair of opposing first side edges and the mold compound includes a pair of opposing second side edges, in which each of the second side edges extends between respective ends of the first side edges and tapers from the substrate to the distal surface.

6. The device of claim 1, wherein the substrate is a lead frame having a plurality of contacts along at least one side thereof that is different from the at least one side edge having the notch.

7. The device of claim 1, wherein the notch extends along the at least one side edge from a mounting surface of the substrate to the distal surface of the mold compound.

8. The device of claim 6, wherein the notch is configured to expose a portion of the die pad, the notch having a curved surface that tapers inwardly from the distal surface to the die pad.

9. A method comprising:
mounting semiconductor devices on die pads of respective lead frames distributed across a substrate having first and second surfaces;
positioning a first mold chase on the first surface of the substrate over the semiconductor devices, the first mold chase including an arrangement of protrusions extending from a surface of a mold cavity aligned with respective edges of the die pads between adjacent pairs of the lead frames;
positioning a second mold chase on the second surface opposite the first mold chase to clamp the substrate between the first and second mold chases;
injecting a mold compound into the mold cavity to encapsulate the semiconductor devices and portions of the substrate; and
singulating the semiconductor devices to provide packaged semiconductor devices.

10. The method of claim 9, wherein, prior to singulating, injecting the mold compound forms a unified volume of the mold compound encapsulating the semiconductor devices with voids at respective locations of each of the protrusions.

11. The method of claim 10, wherein singulating the semiconductor devices includes cutting through the substrate and the mold compound in a direction between adjacent pairs of the lead frames and through the voids.

12. The method of claim 11, wherein cutting through the voids forms respective notches along opposing side edges of each packaged semiconductor device, and the opposing side edges of each packaged semiconductor device have respective surfaces that are parallel to each other and orthogonal a distal planar surface of mold compound spaced, which is spaced from a respective one of the lead frames.

13. The method of claim 9, wherein the first mold chase includes a plurality of mold cavities, in which each mold cavity has a volume configured to contain semiconductor devices arranged in a respective row or column on the first surface of the substrate between respective edges of the substrate.

14. The method of claim 13, wherein each of the mold cavities has spaced apart sidewall edges extending between proximal and distal ends thereof, in which the distal ends thereof are connected by a proximal surface of the respective mold cavity to provide the volume.

15. The method of claim 14, wherein the sidewall edges of each of the mold cavities taper between the proximal and distal ends.

16. The method of claim 9, wherein each of the protrusions extend from a proximal surface of the mold cavity to terminate in a distal end thereof configured to clamp an edge of a respective die pad to a clamping surface of the second mold chase during the injecting.

17. The method of claim 9, further comprising clamping the substrate between the first and second mold chases, in which the first mold chase includes a mold cavity having a volume configured to contain a plurality of the semiconductor devices on the first surface of the substrate and the arrangement of protrusions extending from the surface of the mold cavity aligned with edges of respective die pads of adjacent pairs of the lead frames.

18. A packaged electronic device comprising:
a lead frame having a die pad and contacts along at least one side thereof;
an electronic device on the die pad, the electronic device including pads coupled to respective ones of the contacts; and
a mold compound over the electronic device to provide an encapsulated electronic device, the encapsulated electronic device having first and second pairs of opposing sides and a planar distal surface spaced from the lead frame, the contacts at least partially exposed through the mold compound along the at least one of the first pair of sides, and the mold compound along the second pair of opposing sides includes respective surfaces that are orthogonal to the distal surface and include a respective notch therein.

19. The device of claim 18, wherein the mold compound along the first pair of opposing sides has respective surfaces configured to taper from the lead frame to the distal surface.

20. The device of claim 18, wherein:
the second pair of opposing side are free from contacts for the electronic device, and
the contacts are at least partially exposed through the mold compound along at least one of the first pair of sides.

21. The device of claim 18, wherein the electronic device comprises an integrated circuit die.
